(19) United States
(12) Patent Application Publication
(10) Pub. No.: US 2009/0188745 A1
(43) Pub. Date: Jul. 30, 2009

(54) Helmholz resonator loudspeaker

(76) Inventor: Paul Wilke, Den Haag (NL)

Correspondence Address: Richard Scott Toikka, 11016 Wickshire Way, Rockville, MD, 20852, US

(21) Appl. No.: 12/010,774

(22) Filed: Jan. 30, 2008

(51) Int. Cl. H05K 5/00

(52) U.S. Cl. 181/148

(57) ABSTRACT

An improved Helmholz resonator loudspeaker that may be truncated on one or both ends. The bass pipe is brought partially or completely to extend outside the enclosure, leading to improved efficiency in reproducing lower frequencies. The extended bass pipe may be utilized as part of the mounting structure for the loudspeaker on a base, or may be given an ornamental function.

### CROSS REFERENCE TO RELATED APPLICATIONS

Not Applicable

### STATEMENT REGARDING FEDERALLY SPONSORED RESEARCH OR DEVELOPMENT

Not Applicable

### THE NAMES OF PARTIES TO A JOINT RESEARCH AGREEMENT

Not Applicable

### INCORPORATION BY REFERENCE OF MATERIAL SUBMITTED ON A COMPACT DISK

Not Applicable

### BACKGROUND OF THE INVENTION

(1) Field of the Invention

The present invention is generally directed to loudspeakers, and more particularly to loudspeakers of the Helmholz resonator type. More specifically, the present invention is directed to improving on a Helmholz resonator loudspeaker by extending the bass pipe to the outside of the enclosure, leading to further improvements in its efficiency and to novel applications.

(2) Description of Related Art Including Information Disclosed Under 37 CFR 1.97 and 1.98.

The shape of a Helmholz resonator loudspeaker enclosure, the way dampening material is applied, the location of the loudspeakers and the position and shape of the bass pipe all influence the internal dampening of the resonator, thus effecting its inverse, the Q-factor or quality factor.

For a Helmholz resonator loudspeaker enclosure, a high Q factor is highly desirable for three reasons. First, the more the air in the enclosure can be brought to resonate, the more bass tones are produced by the bass pipe. Second, the more the air in the enclosure can be brought to resonate, the more the movement of the loudspeaker cone will be dampened. Thus, with smaller excursions from the loudspeaker cone, more of the electrical energy fed into it will be translated in to sound. Third, the Q factor of the Helmholz resonator loudspeaker enclosure is important in determining the optimum enclosure size: the higher the value of Q, the smaller the enclosure can be made without degrading bass reproduction.

As mentioned, different factors influence the Q-factor of a Helmholz resonator loudspeaker enclosure. It is believed that a capsule shaped enclosure is optimal for achieving a high Q-factor. However, certainly with very small Helmholz resonator enclosures, non-linear phenomena associated with an increase in sound level can result in a significant lowering of the Q-factor. The underlying cause is air turbulence in both the bass pipe and the enclosure at higher sound levels. This throws the enclosure out of alignment, which can have catastrophic effects on both drivers and sound quality. The fact that the bass pipe is inside the loudspeaker enclosure is a contributing factor to the occurrence of turbulence. By shifting the bass pipe to the outside of the enclosure, much of this factor is eliminated.

In the existing art, bass pipes in Helmholz resonator loudspeaker enclosures are mounted internally, as shown in U.S. Pat. No. 5,710,395 to Wilke.

The extension of the bass pipe to the outside of the enclosure has as an added advantage, that the volume of the enclosure itself is not affected by the volume of the bass pipe as with internal mounting. It is well known in the existing art that, all other things being equal, a larger volume of an enclosure translates into lower frequencies that can be reproduced. Certainly for small loudspeaker enclosures, the volume lost because of the internal mounting of the bass pipe can lead to a significant degradation of bass reproduction.

The extension of the bass pipe outside the enclosure further allows for additional uses. The extended bass pipe can be used for mounting the loudspeaker enclosure behind a surface, for example in television use or applications in the automobile industry. It could also be used as part of a structure allowing the loudspeaker to be placed on a flat surface.

### BRIEF SUMMARY OF THE INVENTION

An object of the present invention is to provide an improved location for the bass pipe in Helmholz resonator loudspeakers by placing it outside the enclosure, thus minimizing turbulent air currents inside the enclosure and by doing so enhancing bass reproduction.

An object of the present invention is to provide an improved location for the bass pipe in Helmholz resonator loudspeakers by placing it outside the enclosure, thus freeing volume inside the enclosure that would have otherwise been occupied by the bass pipe, this further enhancing bass reproduction.

Another object of the present invention is to make use of the bass pipe thus extending from the enclosure to provide for a mounting fixture.

Another object of the present invention is to make use of the bass pipe thus extending from the enclosure to provide for a mounting fixture which, together with a base plate or feet, enables the enclosure to be placed on a hard surface in an upright position.

Another object of the present invention is to make use of the bass pipe thus extending from the enclosure to provide for a mounting fixture which, together with mounting brackets, allows the enclosure to be mounted behind a wall or panel inside television sets, cars or other locations where it is preferred to keep the loudspeaker enclosure hidden from sight.

Another object of the present invention is to make use of the visual analogy with a bottle that is created by the bass pipe extending from a capsule shaped enclosure. This unique shape provides opportunities for display or advertising purposes.

These and other objectives of the present invention are achieved by moving the bass pipe in a Helmholz resonator loudspeaker enclosure to the outside of that enclosure, improving bass reproduction. In combination with a capsule shaped loudspeaker enclosure this is believed to produce a more efficient Helmholz resonator loudspeaker than those known in the existing art.

### BRIEF DESCRIPTION OF THE SEVERAL VIEWS OF THE DRAWINGS

FIG. 1 is a front view and a cross sectional view of the Helmholz resonator loudspeaker with external bass pipe.

FIG.2 is a front view and cross sectional view of the Helmholz resonator loudspeaker with external bass pipe, in which the bass pipe is used as part of the construction for the base consisting of two pieces of shaped flat metal.

FIG.3 is a front view and cross sectional view of the Helmholz resonator loudspeaker with external bass pipe, in which the bass pipe is used as part of the construction for the base consisting of a single piece.

FIG.4 is a front view and cross sectional view of the Helmholz resonator loudspeaker with external bass pipe, in which the bass pipe is shaped to resemble the neck of a bottle.

FIG.5 is a front view and cross sectional view of the Helmholz resonator loudspeaker with external bass pipe with brackets for mounting behind a wall or panel.

FIG. 6 is a front view and cross sectional view of the Helmholz resonator loudspeaker with external bass pipe in which an insertion piece is connected to the base enabling the assembly to be put in an upright position on a hard surface.

### DETAILED DESCRIPTION OF THE INVENTION

In the attached drawing figures, in which like parts are labelled with the same numerals, a number of embodiments is shown for the Helmholz resonator loudspeaker with external bass pipe.

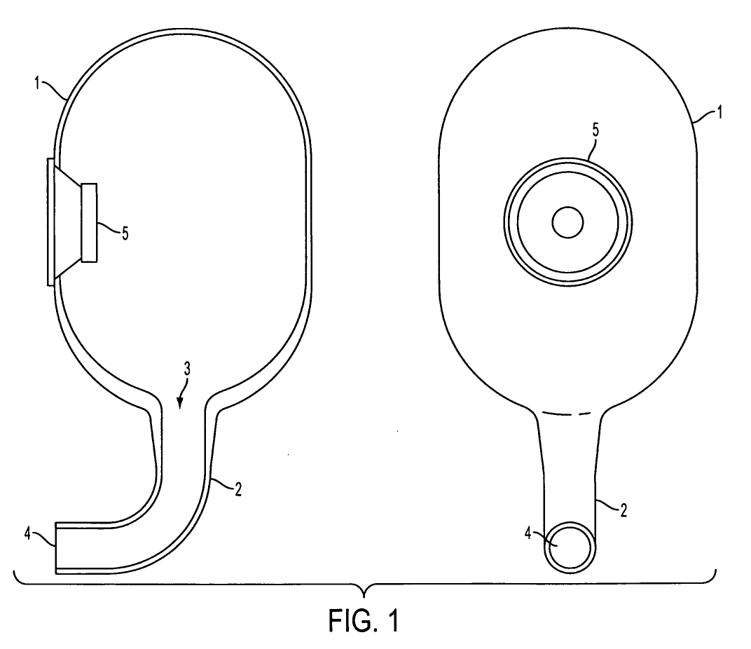

FIG. 1 shows a front view and a cross sectional view of the Helmholz resonator loudspeaker in which the speaker housing 1 is attached to external bass pipe 2. In the preferred embodiment, the speaker housing 1 has a capsule shape in the form of a symmetrical shaped elongated circular body. The external bass pipe is open at the resonance entrance port 3 to the inside of the speaker housing 1 on one side, and the other side is open to the outside air through resonance exit port 4

A speaker 5, having any suitable design but preferably with a total Q of less than 0.7, is mounted by any suitable means so that the axis of the loudspeaker is at right angles with the axis of the tubular portion.

At low frequencies, the volume inside the enclosure and the length and width of the bass pipe can come into resonance, such that in a well calculated system the sound emanating from the speaker 5 and the sound emanating from the resonance exit port 4 mutually reinforce each other. This resonance process creates movement of air within the bass pipe 2 and the speaker housing 1, which at higher levels may lead to ever high levels of turbulence. This turbulence dampens the resonance process within the Helmholz resonator, leading to diminished bass reduction and higher cone movements of speaker 5. At higher sound levels, turbulence may destroy the alignment of the enclosure catastrophically with the potential of causing mechanical damage to speaker 5. In the present invention, there is less overall turbulence, and catastrophic turbulence only occurs at higher sound levels, as compared to loudspeakers in the existing art.

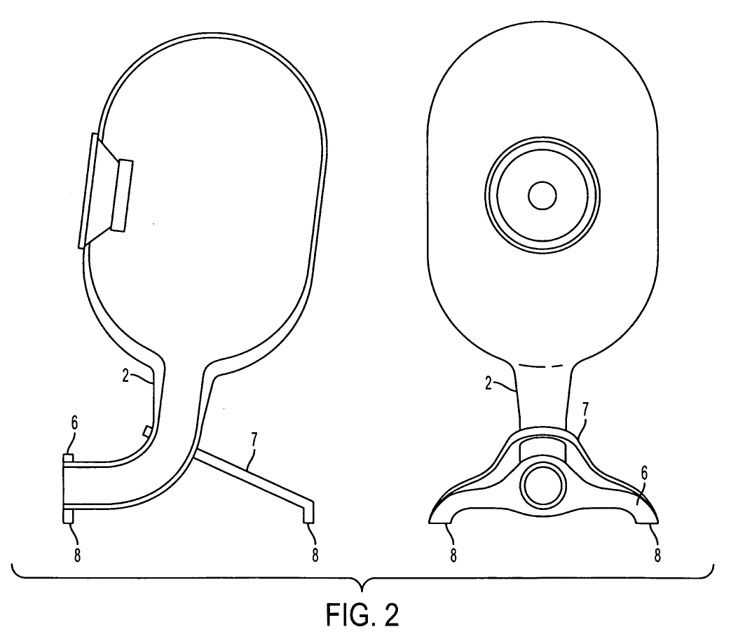

Another embodiment of the present invention is shown in FIG. 2. Two stands 6 and 7 shaped out of flat metal are affixed to the bass pipe 2 in such a way, that they will touch a horizontal plane in four points 8. This allows the loudspeaker to be placed on a flat surface such as a floor or table desk.

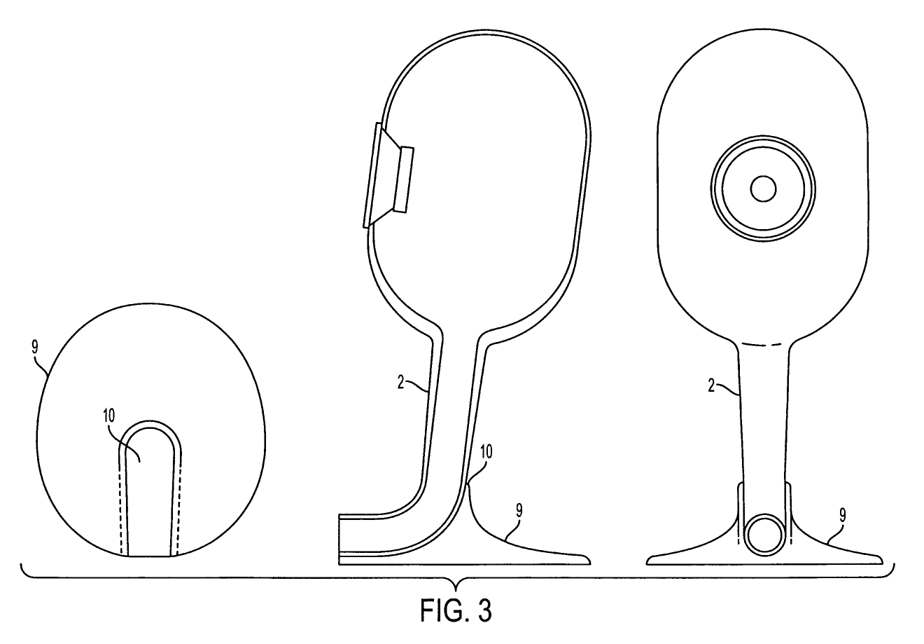

Another embodiment of the present invention is shown in FIG. 3. The bass pipe 2 is nested into a base 9 through a fitting slot 10. This allows the loudspeaker to be placed on a flat surface such as a floor or table desk.

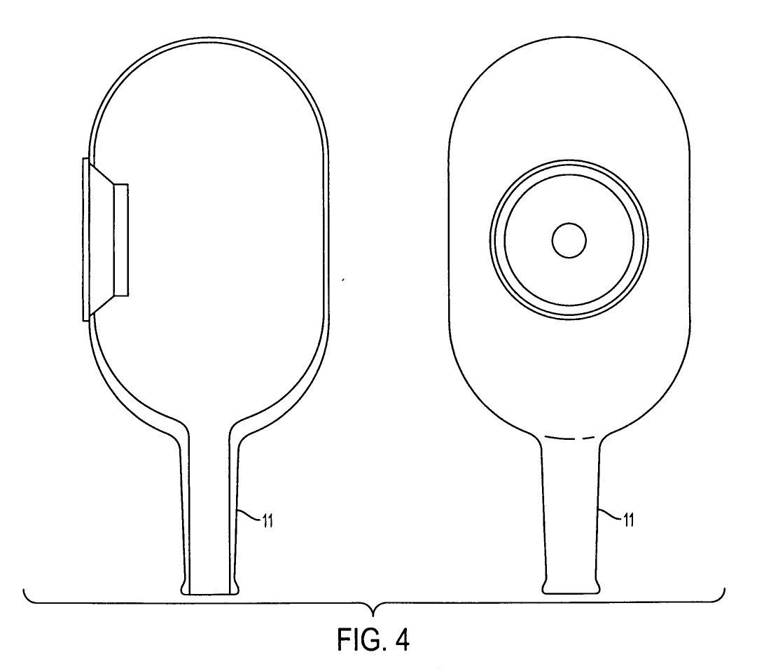

Another embodiment of the present invention is shown in FIG.4. Bass pipe 11 is shaped in the form of a bottle neck, giving the whole loudspeaker the appearance of a bottle.

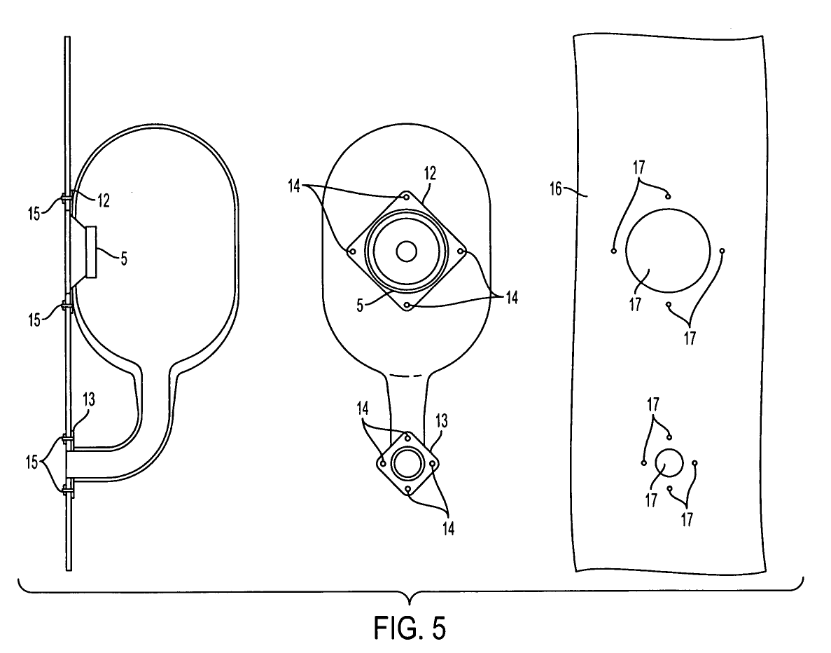

Another embodiment of the present invention is shown in FIG. 5. Two flanges 12 and 13 are mounted to respectively the speaker 5 and the resonance exit port 4, with holes 14 wire-tapped to receive bolts 15. The enclosure can thus be affixed to a wall or panel 16 with holes 17 at the appropriate locations. This allows the present invention to be mounted invisibly inside automobiles, appliances like TV's, or behind walls.

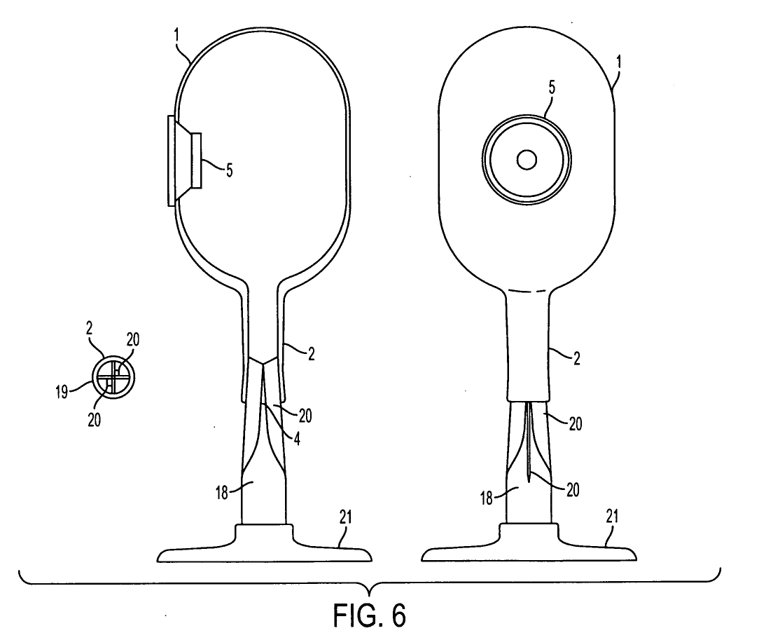

Another embodiment of the present invention is shown in FIG. 6. Here, an insertion piece 18 is connected to the inside of the bass pipe 2 at the end of resonance exit port 4. As in cut-through 19 is shown, four extenders 20 keep insertion piece 18 from the walls of the bass pipe 2, allowing free movement of air through exit port 4 and bass pipe 2. Insertion piece 18 is connected to base 21, enabling the assembly to be put in an upright position on a hard surface.

The scope for this invention is such that various other embodiments and modifications and improvements not described herein may lay within the spirit and scope of the present invention, as defined by the following claims.

I claim:

1. A Helmholz resonator loudspeaker in which the bass pipe is external to the loudspeaker enclosure.

2. The Helmholz resonator loudspeaker as in claim 1, in which the external bass pipe is attached to a base for vertical mounting of said loudspeaker.

3. The Helmholz resonator loudspeaker as in claim 1, in which the external bass pipe is attached to a base for vertical mounting of said loudspeaker by means of an insertion piece connected to the inside of the bass pipe.

4. The Helmholz resonator loudspeaker as in claim 1, in which mounting flanges are affixed so that the loudspeaker can be used for mounting behind a panel or wall.
